(19) United States
(12) Patent Application Publication
(10) Pub. No.: US 2008/0220733 A1
(43) Pub. Date: Sep. 11, 2008

(54) Fast frequency range selection in ranged controlled oscillators

(75) Inventor: Earl W. McCune, Santa Clara, CA (US)

Correspondence Address: PATENT LAW PROFESSIONALS, P.O. BOX 612407, SAN JOSE, CA, 95161, US

(73) Assignee: Matsushita Electric Industrial Co., Ltd.

(21) Appl. No.: 11/713,169

(22) Filed: Mar. 2, 2007

(51) Int. Cl. H03L 7/00

(52) U.S. Cl. 455/118; 331/16

(57) ABSTRACT

Methods and apparatus for fast frequency range selection in ranged controlled oscillators. An exemplary frequency range selection apparatus includes a ranged voltage controlled oscillator (VCO) configured within a frequency control loop (e.g., within a phase-locked loop (PLL)), and a range select controller. The range select controller is configured to receive a phase difference signal from a frequency/phase detector and a fine tuning signal from the output of a loop filter. The range select controller uses the error and fine tuning signals to determine which range setting code should be applied to the range setting input of the VCO. The ability to use information obtained exclusively from the control loop avoids the need to perform a separate open-loop range selection process, as is required in prior art range selection approaches. Because the control loop never needs to be opened, the range selection process is substantially less time consuming compared to prior art approaches.

### FIELD OF THE INVENTION

The present invention relates generally to ranged controlled oscillators. More specifically, the present invention relates to methods and apparatus for achieving fast frequency range selection in ranged controlled oscillators.

### BACKGROUND OF THE INVENTION

A voltage controlled oscillator (or “VCO”) is a special type of electrical oscillator that generates an oscillatory signal having a frequency that is dependent on a control voltage. VCOs play an important role in communication systems and other electronic systems. They are used in both analog and digital systems, and are essential components in virtually every radio frequency (RF) communication system. FIG. 1 shows, for example, how a VCO is configured in the front end of a conventional RF communications transceiver 100. In this particular application, a VCO is configured as a local oscillator (LO) 102 for first and second mixers 104 and 106. The first and second mixers use the frequency provided by the LO 102 to down-convert RF signals received by the transceiver 100 to a lower frequency and to upconvert signals to be transmitted by the transceiver 100 to a higher frequency.

Because the output frequency of a VCO has a tendency to drift, the VCO is typically configured within a phase-locked loop (PLL) circuit. The PLL circuit functions to force the VCO to lock to a frequency (or a multiple of the frequency) of a signal provided by a highly stable frequency source such as, for example, a crystal oscillator. FIG. 2 is a diagram of a typical PLL circuit 200. The PLL circuit 200 comprises a phase detector 202, a loop filter 204, a VCO 206, and a frequency divider 208. A first input of the phase detector 202 is configured to receive a reference signal having a precise and stable reference frequency f_{ref}. This reference signal frequency f_{ref} is commonly derived from the resonant frequency of mechanical vibration of a crystal, such as quartz. A second input of the phase detector 202 is configured to receive a feedback signal having a frequency f₀/N, where f₀ represents the frequency of the VCO output signal and N represents a divisor provided by the frequency divider 208. Action of the feedback loop causes the frequency f₀/N to equal f_{ref}. Equivalently, the VCO output frequency is driven to be equal to N×f_{ref}. Varying N provides the PLL circuit 200 the ability to synthesize frequencies that are multiples of the reference frequency f_{ref}.

In particular, when the divided VCO output signal frequency f₀/N deviates from the reference signal frequency f_{ref}, the phase detector 202 operates to provide a semi-periodic phase difference signal (or “error signal”) at its output. The error signal represents the degree by which the two frequencies are misaligned. The loop filter 204 operates as an integrator that generates a filtered error signal based on the error signal generated by the phase detector 202. The filtered error signal is applied to a voltage control input of the VCO 206, and causes the divided VCO output signal frequency f₀/N to change in the direction of the reference frequency f_{ref}. The corrected VCO output signal frequency f₀/N is fed back to the phase detector 202 input. The phase detection and error correction processes are repeated until the divided VCO output signal frequency f₀/N is forced to equal the reference signal frequency f_{ref}. When this condition is realized the PLL circuit 200 is said to be “locked.”

Modern electronic systems, such as for example, radio communication systems, are often required to operate over wide frequency ranges. To satisfy this requirement, the VCOs used in such systems must have a wide tuning range. FIG. 3 is a drawing of a step-ranged resonant inductive-capacitive (LC) differential oscillator 300, which is one type of oscillator that is capable of being tuned over a wide tuning range. The step-ranged LC differential oscillator 300 comprises first and second cross-coupled transistors 302 and 304, first and second varactor diodes 306 and 308, a variable capacitor bank 310, and first and second inductors 312 and 314. A varactor diode is a special type of diode that provides a variable capacitance having a value that depends on the voltage applied across its terminals. The first and second varactor diodes 306 and 308 in the oscillator 300 are used to fine tune the oscillator once the oscillator 300 has been coarsely tuned to the appropriate frequency range. The variable capacitor bank 310, which is used to coarse tune the VCO, is typically implemented in the form of a switched array of binary weighted capacitors. The capacitances contributed by the first and second varactor diodes 306, 308 and the variable capacitor bank 310, together with the first and second inductors 312, 314, form an inductive-capacitive (i.e., LC) tank circuit. Ideally, the LC tank circuit has zero resistance, which allows the oscillator 300 to oscillate indefinitely. However, because the capacitors and inductors are not ideal (they all include some resistance), the oscillator is unable to continue oscillating unabated. To overcome this problem, a negative resistance provided by the first and second transistors 302, 304 is employed to counteract the non-idealities.

FIG. 4 illustrates how a step-ranged VCO 410 is typically configured in a PLL circuit 400. Similar to the PLL circuit 200 in FIG. 2, the PLL circuit 400 in FIG. 4 includes a phase detector 402, a loop filter 404 and a frequency divider 406. The PLL circuit 400 further includes a loop switch 408, a step-ranged VCO 410 and, finally, an adjustment process 412. The adjustment process 412 includes first and second inputs, which are configured to receive a tuning command 414 and the output signal provided by the step-ranged VCO 410, respectively.

In response to a tuning command, the PLL circuit 400 performs a two-step process—a coarse tuning process and a fine tuning process. The coarse tuning process is performed with the first and second varactor diodes 306, 308 biased at some constant value (e.g., midway (or V/2) between the fine tuning voltage range of the step-ranged VCO 410) and with the main control loop of the PLL circuit 400 open. In response to changes in the tuning command applied to the PLL circuit 400, the adjustment process 412 sends range select codes to a range select input of the VCO 410. Each range select code (i.e., coarse tuning code) switches one or more capacitors into or out of the switched array of binary weighted capacitors 310. The adjustment process 412 steps through the range select codes, and the output frequency of the step-ranged VCO 410 is measured, until the frequency provided by the VCO 414 is coarsely tuned to the frequency specified by the tuning command.

The plurality of possible coarse frequency settings provided by the step-ranged VCO 410 is represented by the horizontally disposed dots at V/2 in FIG. 5. For each coarse frequency setting, a fine tuning process (represented by the slanted voltage curves in FIG. 5) is available which allows the VCO 414 to be fine tuned over a narrow frequency range. The fine tuning process is initiated by closing the main control loop of the PLL circuit 400 (i.e., by connecting the loop switch 408 to Vtune in FIG. 4) after the coarse tuning process has been completed. After the loop is closed, the PLL circuit 400 operates in a manner similar to that described above in connection with FIG. 2. So long as the initial coarse frequency setting is within the fine tuning range offered by the variable capacitance varactor diodes 306, 308, the PLL circuit 400 will operate to fine tune (i.e., lock) the VCO output signal frequency to the target frequency specified by the tuning command.

Although the prior art step-ranged VCO approach described above is capable of tuning over a wide tuning range, it has various drawbacks. First, the open-loop range selection process (i.e., coarse tuning process) can take a considerable amount of time to complete. Second, there is a substantial settling transient that the PLL circuit 400 must respond to once the control loop is closed after completing the coarse tuning process. This transient results from the adjustment process 412 not having any information concerning what the loop phase error is, and from the voltage discontinuity present at the voltage control input of the VCO 410 at the start of the fine tuning process. Prior to the loop switch 408 closing the control loop the voltage at the control input of the VCO is at V/2. However, immediately after the loop is closed the voltage at the control input does not equal V/2. Rather, it is at whatever voltage the loop filter 404 happens to be providing at that time. Because this voltage can be at any arbitrary value, a voltage discontinuity occurs when the loop switch 408 closes the control loop.

The time needed to complete the open loop range select process, along with the time the PLL circuit 400 needs to respond to the transients that occur after the control loop is closed, can be quite long. Unfortunately, in applications where the VCO 410 must change its frequency rapidly (e.g., in radio communication applications) the amount of time can be unacceptable. What are needed, therefore, are methods and apparatus of calibrating step-ranged VCOs that do not require a separate, open-loop range selection process, and which have fast acquisition and settling times.

### SUMMARY OF THE INVENTION

Methods and apparatus for fast range selection in ranged controlled oscillators are disclosed. An exemplary frequency range selection apparatus includes a ranged voltage controlled oscillator (VCO) configured within a frequency control loop (e.g., within a phase-locked loop (PLL)), and a range select controller. The range select controller is configured to receive information from the control loop, and use the received information to determine which one of a plurality of range select codes should be applied to a range setting input of the VCO. The range select controller has first and second inputs for receiving the control loop information. The first input is configured to receive a phase difference signal from a frequency/phase detector disposed within the control loop. The phase difference signal (or “error signal”) provides an indication of the degree by which the frequency of a frequency divided output of the VCO differs from a reference signal frequency. The second input is configured to receive a fine tuning signal from the output of a loop filter, which is also disposed in the frequency control loop. The range select controller uses the error and fine tuning signals to determine which range setting code should be applied to the range setting input of the VCO. The ability to use information obtained exclusively from the control loop avoids the need to perform a separate open-loop range selection process, as is required in prior art range selection approaches. Because the control loop never needs to be opened, the range selection process is substantially shorter compared to prior art approaches.

Other features and advantages of the present invention will be understood upon reading and understanding the detailed description of the preferred exemplary embodiments, found hereinbelow, in conjunction with reference to the drawings, a brief description of which are provided below.

### BRIEF DESCRIPTION OF THE DRAWINGS

FIG. 1 is a simplified block diagram illustrating how a voltage controlled oscillator (VCO) is configured in a conventional communications transceiver;

FIG. 2 is a block diagram of a phase-locked loop (PLL) circuit;

FIG. 3 is a schematic drawing of a step-ranged resonant inductive-capacitive (LC) differential oscillator;

FIG. 4 is block diagram illustrating how a step-ranged VCO, such as the step-ranged VCO in FIG. 3, is typically configured in a PLL circuit;

FIG. 5 is a range setting and tuning voltage chart of a step-ranged VCO;

FIG. 6 is a block diagram of a PLL circuit having a step-ranged VCO, according to an embodiment of the present invention;

FIGS. 7A-F are range selection and frequency acquisition plots that illustrate various examples of operation of the PLL circuit with the step-ranged VCO in FIG. 6;

FIG. 8 is a plot illustrating how the PLL circuit with the step-ranged VCO in FIG. 6 operates when the PLL circuit is cold-started without any range estimate available;

FIG. 9 is a flow chart illustrating the range selection and frequency tuning process performed by the PLL circuit with the step-ranged VCO in FIG. 6, according to an embodiment of the present invention;

FIG. 10 is a block diagram illustrating how the PLL circuit with the step-ranged VCO in FIG. 6 may be employed in a radio frequency (RF) transmitter, according to an embodiment of the present invention; and

FIG. 11 is a block diagram illustrating how the PLL circuit with the step-ranged VCO in FIG. 6 may be employed in a radio frequency (RF) polar transmitter, according to an embodiment of the present invention.

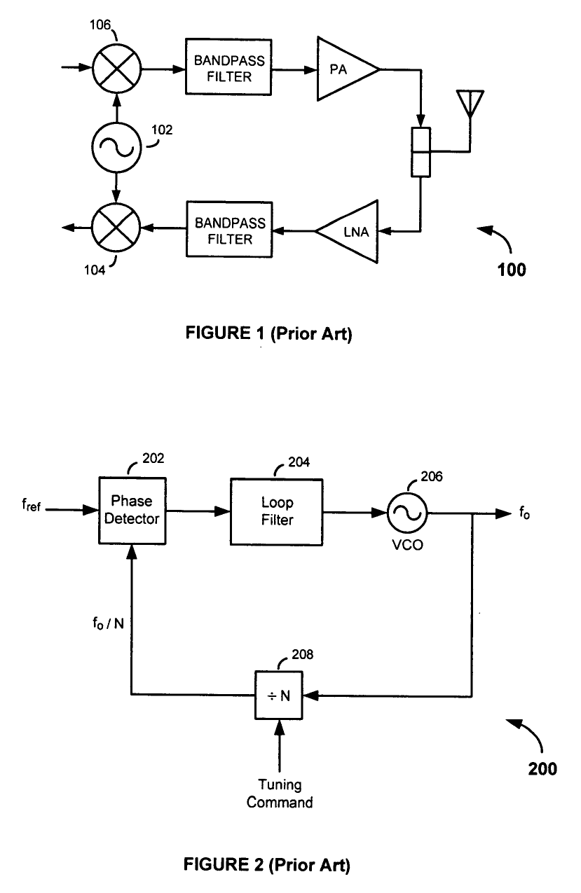

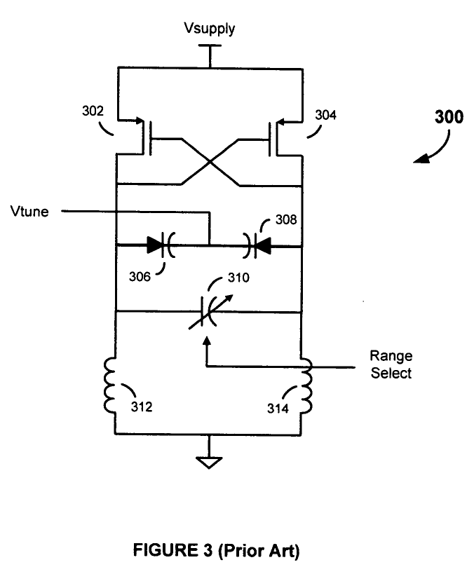

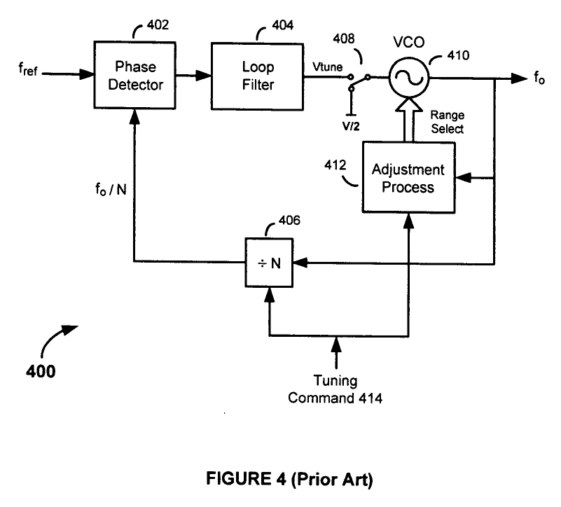

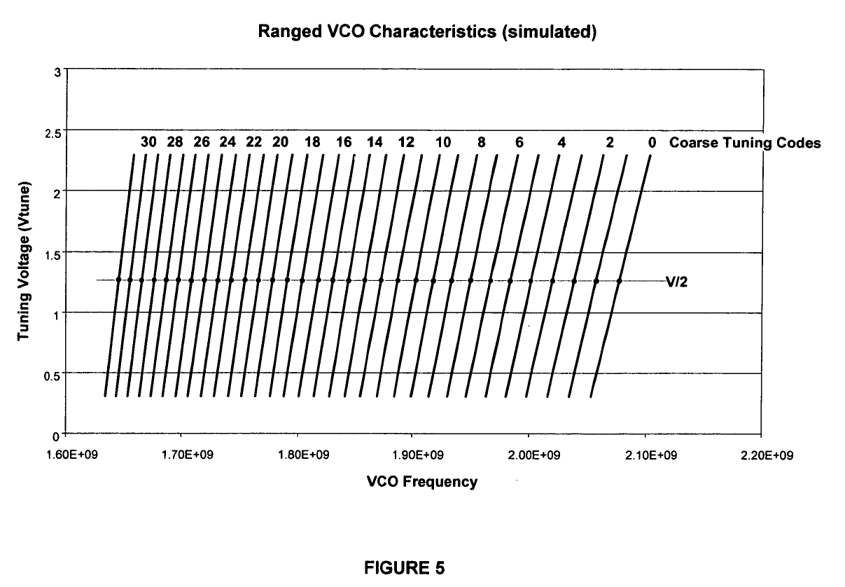

### DETAILED DESCRIPTION

Those of ordinary skill in the art will realize that the following detailed description of the present invention is illustrative only and is not intended to be in any way limiting. Other embodiments of the present invention will readily suggest themselves to such skilled persons having the benefit of this disclosure. Reference will now be made in detail to implementations of the present invention as illustrated in the accompanying drawings. The same reference indicators will be used throughout the drawings and the following detailed description to refer to the same or like parts.

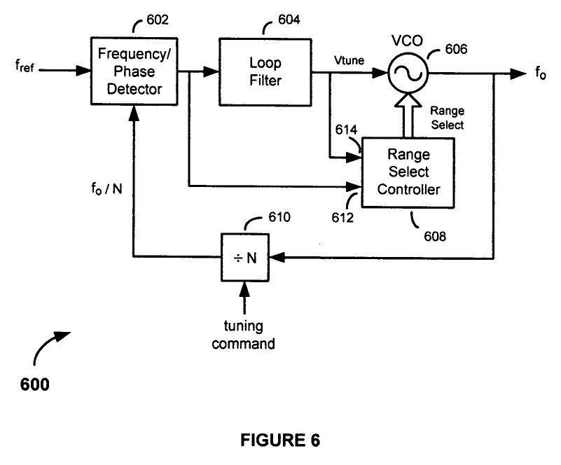

Referring first to FIG. 6, there is shown a phase-locked loop (PLL) circuit 600 having a step-ranged VCO, according to an embodiment of the present invention. As shown, the PLL circuit 600 includes a frequency/phase detector 602, a loop filter 604, a step-ranged VCO 606, a range select controller 608, and a frequency divider 610. The phase detector 602 is operable to provide a periodic phase difference signal, based on a frequency difference between a reference signal having a frequency f_{ref} and a feedback signal having a frequency f₀/N, where f₀ represents the frequency of the VCO output signal and N represents a divisor provided by the frequency divider 610. The loop filter 604 is configured to receive the phase difference signal from the phase detector 602 and provide a tuning voltage, Vtune, to a voltage control input of the step-ranged VCO 606.

According to one embodiment of the invention, the range select controller 608 receives information from the control loop at first and second control inputs 612 and 614, which are configured to receive the phase difference signal provided by the phase detector 602 and the tuning voltage Vtune from the loop filter 604, respectively. In this manner the range select controller 608 is able to use information obtained exclusively from the control loop of the PLL circuit 600 to generate and provide the appropriate range select code. The ability to use information from the control loop of the PLL circuit 600 obviates any need to perform a separate open-loop frequency measurement and range selection process, as is required in prior art approaches. Because the control loop never needs to be opened, the time needed to perform range selection is substantially reduced compared to prior art approaches.

The range select controller 608 may be implemented in various ways. According to one embodiment it is implemented as a simple UP/DOWN counter. The UP/DOWN counter is operable to increment to a range selection code corresponding to a higher frequency range when the difference signal provided by the phase detector 602 (monitored at the first input 612 of the range select controller 608) is increasing and the tuning voltage Vtune at the output of the loop filter 604 (monitored at the second input 614 of the range select controller 608) is determined to have exceeded some upper tuning threshold associated with the upper tuning voltage rail. Conversely, the UP/DOWN counter is operable to decrement to a range selection code corresponding to a lower frequency range when the difference signal provided by the phase detector 602 is decreasing and the tuning voltage Vtune is determined to have dropped below a lower tuning threshold associated with the lower tuning voltage rail. When the tuning voltage Vtune is between the upper and lower tuning voltage thresholds, the counter is held so that it neither increments nor decrements. Selection of threshold settings can take many issues into account, including for example, which type of modulation (if any) is intended to be generated. While the range select controller 608 has been described as being implemented using an UP/DOWN counter, those of ordinary skill in the art will readily appreciate that other ways of generating and controlling the range selection codes using the information from within the control loop of the PLL may be employed.

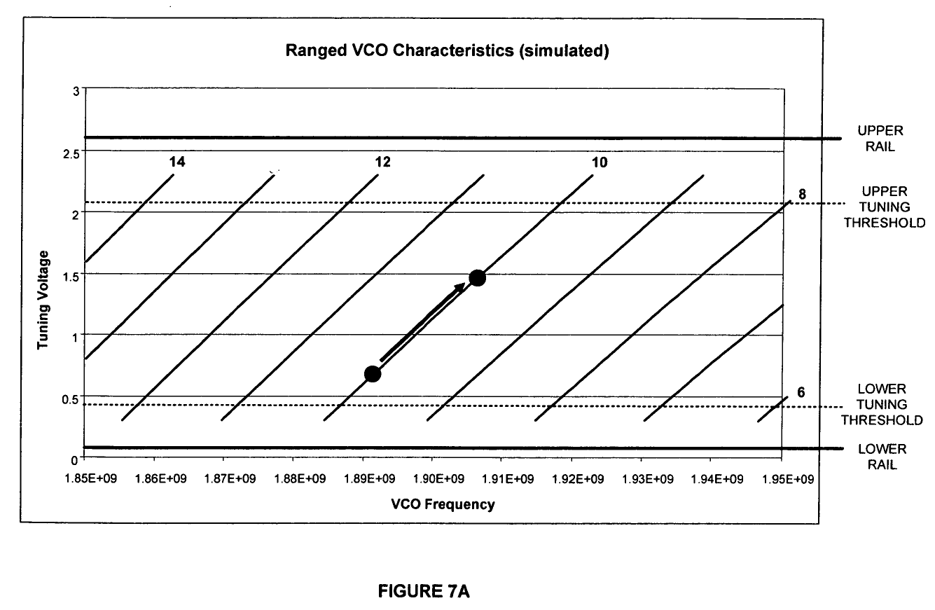

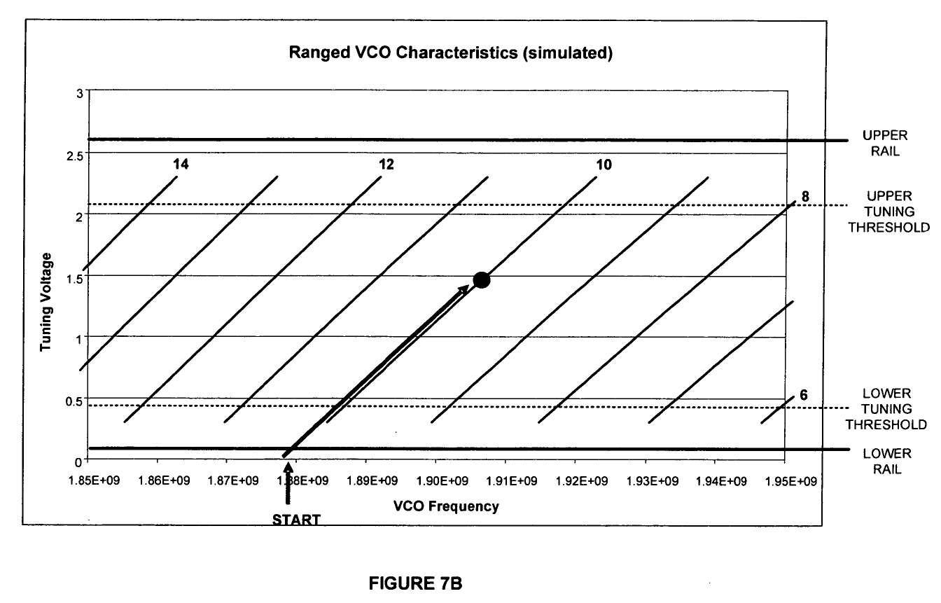

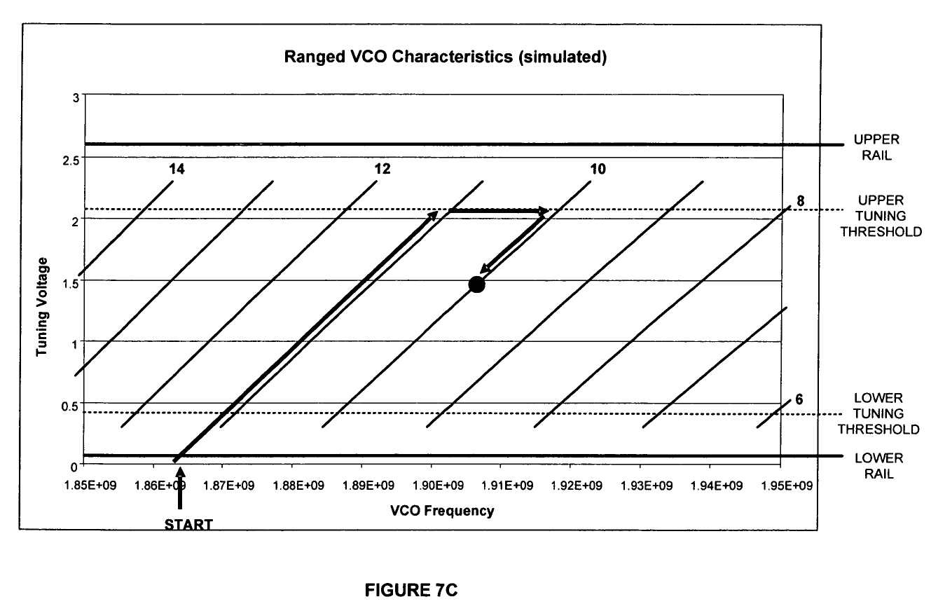

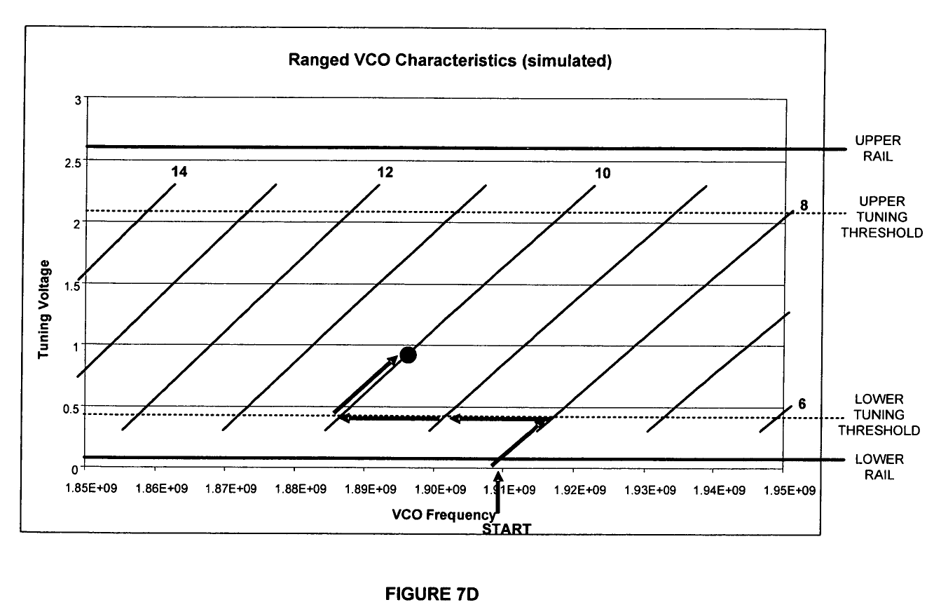

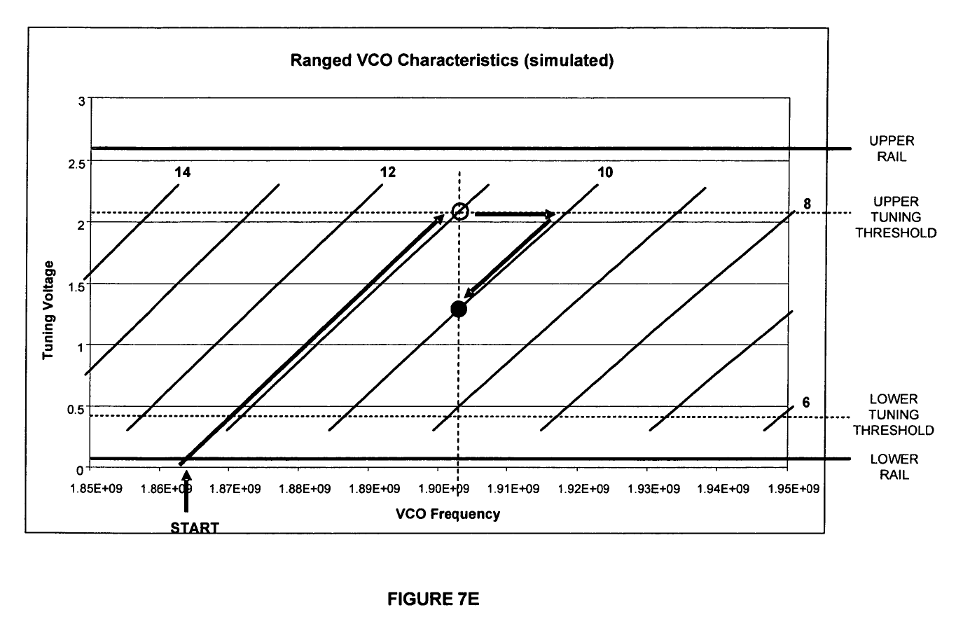

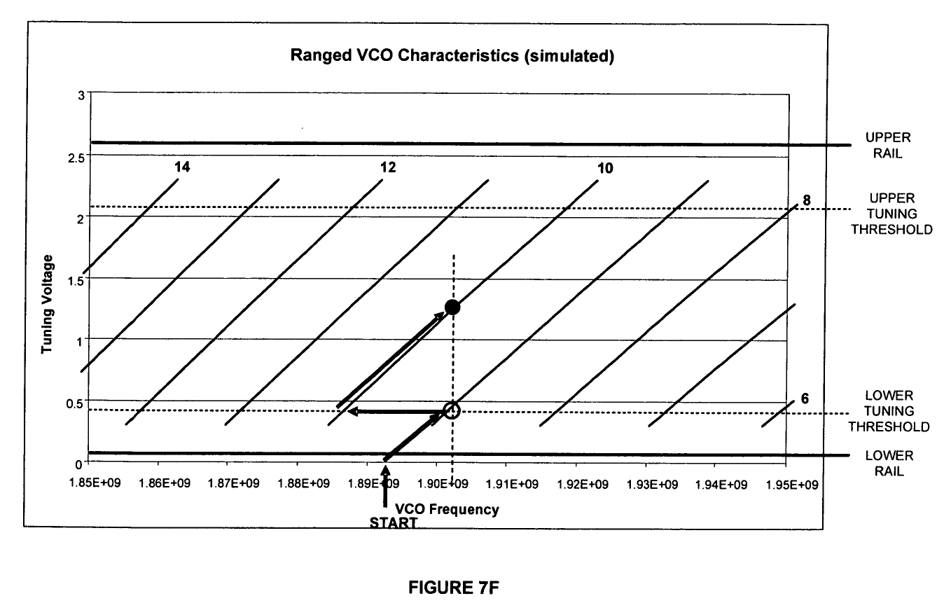

Operation of the PLL circuit 600 in FIG. 6 can be illustrated by the examples provided in FIGS. 7A-7F. FIG. 7A illustrates operation when the range selected by the range select controller 608 is already set to a range that allows the loop to stabilize to the target frequency specified by a new tuning command. When the new tuning command is received, the feedback action of the PLL operates to force the VCO 606 to stabilize to a frequency that is N times the frequency specified by the tuning command. No change in the range select code provided by the range select controller 604 is necessary given these changes in operating conditions.

FIG. 7B illustrates operation of the PLL circuit 600 when cold started (i.e., when Vtune is initially equal to zero volts) and the VCO 606 is configured at an estimated range setting that correctly corresponds to a range setting needed to provide the target output frequency. Techniques that may be used to configure the VCO 606 at an estimated range setting are described in co-pending and commonly assigned U.S. patent application Ser. No. 11/326,645, entitled “An Apparatus and Method for Operating a Variable Segment Oscillator,” which was filed on Jan. 6, 2006, and which is hereby incorporated by reference. Because the estimated range setting is correctly set in this example, no change in the range select code provided by the range select controller 604 is necessary. Similar to the example in FIG. 7A, the feedback action of the PLL circuit 600, by itself, is capable of forcing the VCO 606 to stabilize to a frequency that is N times the frequency specified by the tuning command.

FIG. 7C illustrates operation of the PLL circuit 600 when cold started and the range select controller 608 is initially configured to provide an estimated range setting that is too low. Following the cold start, the PLL circuit 600 operates to try and force the VCO 606 to the target output frequency. As this process continues the output voltage of the loop filter 604 (i.e., Vtune) increases. The range select controller 608 monitors the increasing Vtune at the second input 614 of the range select controller 608. When Vtune reaches the upper tuning limit (i.e., the upper rail), or has reached some predetermined threshold away from the upper tuning limit (i.e., upper tuning threshold), it is an indication to the range select controller 608 that the loop won't be able to stabilize at the existing range setting. This information is used by the range select controller 608 to direct the VCO 606 to step up to the next range setting (e.g., by incrementing its UP/DOWN counter, as described in the example above). After stepping the range setting up one or more times, the error sign at the output of the phase detector 602 of the PLL circuit 600 eventually changes. The change in error sign is detected at the first input 612 of the range select controller 608, and is used to indicate that the proper range setting has been selected. The PLL circuit 600 then operates to slew Vtune down until the loop locks to the desired target frequency.

FIG. 7D illustrates operation of the PLL circuit 600 when cold started and the range select controller 608 is initially configured to provide an estimated range that is too high. Following the cold start, a change in error sign at the output of the phase detector 602 provides an indication at the first input 612 of the range select controller 608 that the range setting currently being applied to the VCO 606 is too high. This information is used by the range select controller 608 to direct the VCO 606 to step down to the next selected range (e.g., by decrementing its UP/DOWN counter, as described in the example above). As the range setting of the range select controller 608 is stepped down, the error sign at the output of the phase detector 602 of the PLL circuit 600 eventually changes. The change in error sign is detected at the first input 612 of the range select controller 608, and is used to indicate that the proper range setting has been selected. The PLL circuit 600 then operates to slew Vtune up until the loop locks to the target frequency.

FIG. 7E illustrates operation of the PLL circuit 600 when the lock point (open circle in drawing) is too close to the upper tuning voltage rail. In this case the range select setting at cold start is sufficient for the loop filter 604 to stabilize, but the tuning voltage Vtune is at or above some predetermined upper tuning voltage threshold. Under these circumstances, it is desirable to determine a different frequency range that can provide the same target frequency but at a Vtune that is more toward the center of the tuning range. According to this aspect of the invention, the range select controller 608 detects at its second input 614 that the tuning voltage Vtune is too close to the upper tuning voltage rail. The range select controller 608 uses this information to provide a range select code that causes the VCO 606 to step up to the next frequency range (e.g., by incrementing the UP/DOWN counter of the range select controller 608, as in the example discussed above). Once the range select controller 608 detects a change in error sign at its first input 612, the range setting is held and the PLL operates to slew Vtune down until it finally locks at the desired target frequency. A similar process can be performed when the lock point is too close to the lower tuning voltage rail (see FIG. 7F).

The times required for each of the tuning processes in FIGS. 7A-F to select the appropriate range select setting can be reduced if a proper estimate of the required tuning range can be accurately made. In some applications an estimate of the correct range setting may not be available or cannot be made. Even without a an estimated range, however, the methods and apparatus of the present invention are capable of determining and setting the VCO 606 to the proper range setting. FIG. 8 shows, for example, a range selection process performed by the PLL circuit 600 in FIG. 6 after a cold start and without any range estimate available. After the cold start, the PLL circuit 600 attempts to stabilize in the range setting specified by the range select controller 608. Because the target frequency is well above the frequency that can be provided at the initial range setting, the loop cannot stabilize and the tuning voltage Vtune increases. The range select controller 608 monitors this increase in Vtune at its second input 614. When Vtune rails (or exceeds some predetermined threshold), the range select controller steps to a higher frequency range (e.g., by incrementing its UP/DOWN counter, as described in the example above). According to one embodiment of the invention, multiple and consecutive range steps are made, one step at a time, until the range select controller 608 detects that the error sign at the output of the phase detector 602 has changed sign. When the sign change is detected, the range setting is held at its current value and the PLL circuit 600 operates to slew Vtune down so that the final target frequency is realized.

In an alternative embodiment, a “binary tree” technique is used to determine the appropriate range setting. According to this approach, rather than configuring the VCO at consecutive step settings until the correct setting is located, the range select controller 608 operates to step half-way between the lowest and highest possible range select settings. If the range setting following the range step proves to be too high, the range select controller 608 steps half way down from the current range setting to the lowest possible range setting. If the range setting following this range step proves to be too low, the range select controller 608 steps half way up to last highest selected range setting. This process continues until a change in the error sign at the output of the phase detector 602 is measured at the first input 612 of the PLL circuit 600. As explained above, the change in error sign provides an indication to the range select controller 608 that the appropriate range setting has been found.

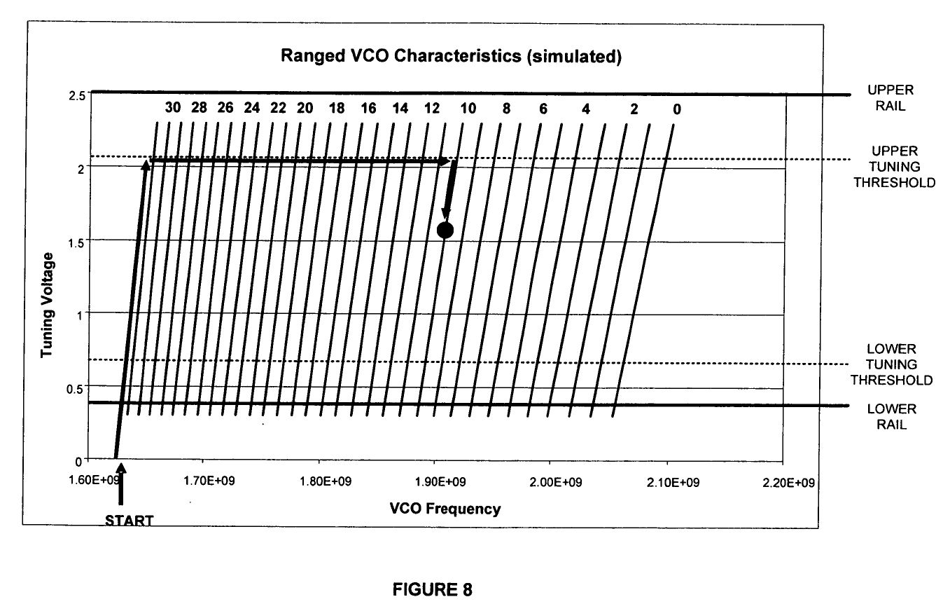

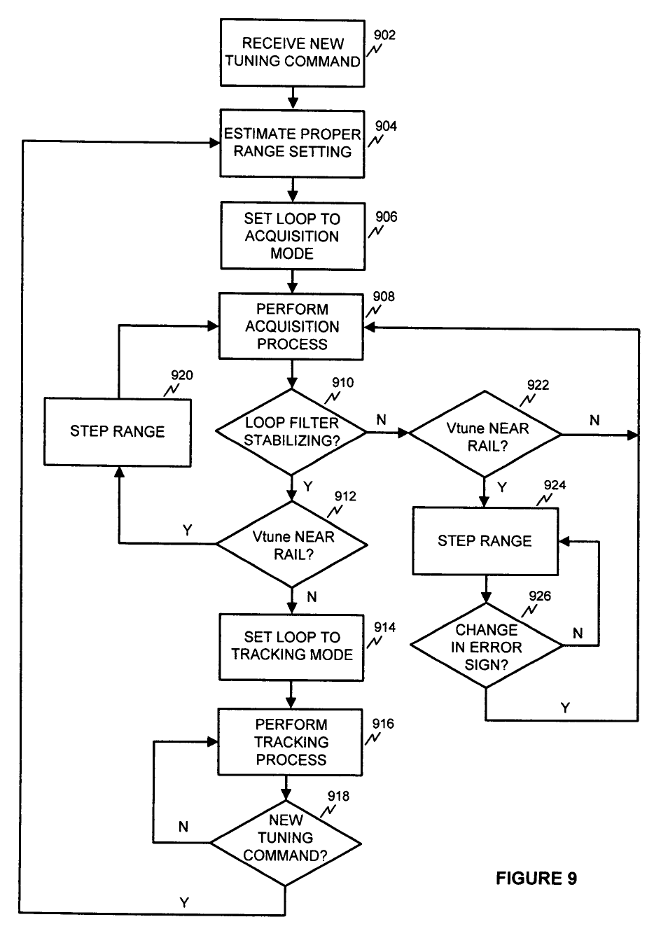

FIG. 9 is a flow chart illustrating in more detail the range selection and frequency acquisition processes performed by the PLL circuit 600, including those described in the examples in FIGS. 7A-F and 8 above, according to an embodiment of the invention. First, at step 902, a new tuning command is received by the PLL 600. Next, at step 904, an estimate of the range setting needed to set the VCO 606 to the frequency specified by the tuning command is made, and a corresponding range select code is applied to the VCO 606. After the range select code is applied to the VCO 606, the PLL circuit 600 is set to an acquisition mode at step 906, which is a mode in which the PLL circuit 600 attempts to acquire the reference frequency f_{ref}, and the loop commences the acquisition process at step 908.

After a predetermined amount of time has expired during the acquisition process in step 908, at decision 910 it is determined whether the loop filter 604 is stabilizing. If the loop filter 604 has stabilized, at decision 912 it is determined whether the output voltage of the loop filter 604 (i.e., Vtune) is near the lower or upper tuning rails, or is within some predetermined threshold of the lower tuning or upper tuning rails, before the loop is set to tracking mode. If the tuning voltage Vtune is between the lower and upper tuning voltage rails (or thresholds) for the selected VCO range, at step 914 the PLL 600 is set to tracking mode, and operates in tracking mode at step 916 until at decision 918 it is determined that a new tuning command has been received. If, on the other hand, at decision 912 it is determined that Vtune, is less than the lower tuning voltage rail (or threshold), or is greater than the upper tuning voltage rail (or threshold), at step 920 the range select code provided by the range select controller 608 is stepped to another level (up or down, depending on whether the tuning voltage is too high or too low), and the acquisition process beginning at step 908 is repeated.

If at decision 910 it is determined that the loop filter 604 is not stabilizing after a predetermined period of time, at decision 922 it is determined whether the output voltage of the loop filter 604 (i.e., Vtune) is near the lower or upper tuning rail, or is within some predetermined threshold of the lower tuning rail or upper tuning rail. If the tuning voltage, Vtune is between the lower and upper rails (or thresholds), the acquisition process beginning at step 908 is repeated until at decision 910 it is determined that the loop filter 604 has stabilized. However, if the tuning voltage Vtune is determined to be less than the lower tuning voltage rail (or threshold), or determined to be greater than the upper tuning voltage rail (or threshold), at step 924 the range select code provided by the range select controller 608 is stepped to another level (up or down, depending on whether the tuning voltage is too high or too low). Then, at decision 926, it is determined whether the error sign provided by the phase detector 602 has changed sign. If the error sign is determined to not have changed at the new range setting, the step range adjustment in step 924 is repeated until decision 926 detects a change in error sign. When a change in error sign is detected, the acquisition process beginning at step 908 is repeated. Once the loop has stabilized and it is determined that the tuning voltage Vtune is between the lower and upper tuning rails (or thresholds), the PLL 600 is set to operate in tracking mode. The loop then remains in tracking mode until a new tuning command is detected at decision 918.

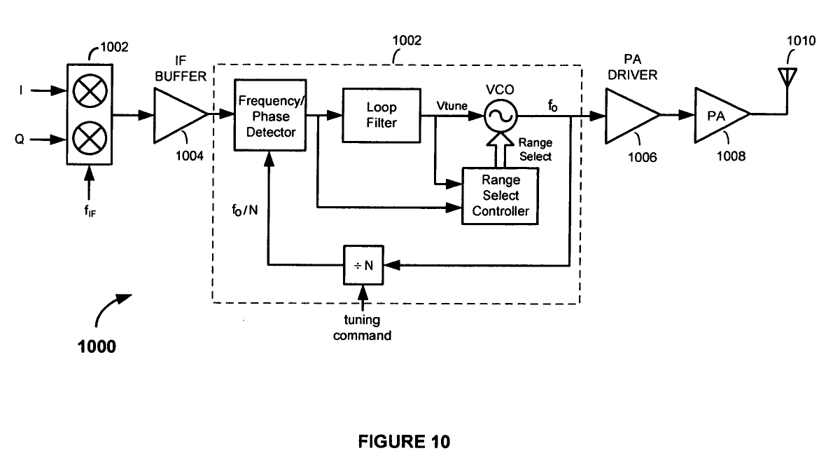

The VCO range selection methods and apparatus described above may be used in a variety of applications, including radio communication applications where fast settling times are of great importance. FIG. 10 shows, as an example, how the PLL circuit with the step-ranged VCO in FIG. 6 may be used as a tracking loop 1002 in a radio frequency (RF) transmitter 1000 for a mobile handset (e.g., a cell phone, personal digital assistant (PDA), handheld computer, or other wireless communication device). Modulated in-phase (I) and quadrature (Q) baseband signals containing information to be transmitted are applied to a quadrature mixer 1002 configured to operate at an intermediate frequency (IF). The IF signals are coupled to the input of the tracking loop 1002, via an IF buffer 1004. The tracking loop is operable to translate the IF signals to RF (i.e., to the RF carrier frequency (f₀)), which are then coupled to a power amplifier (PA) 1006, via a PA driver 1008. The amplifier RF signal is then coupled to an antenna 1010, which radiates the RF signal to a remote receiver (e.g., a cellular base station).

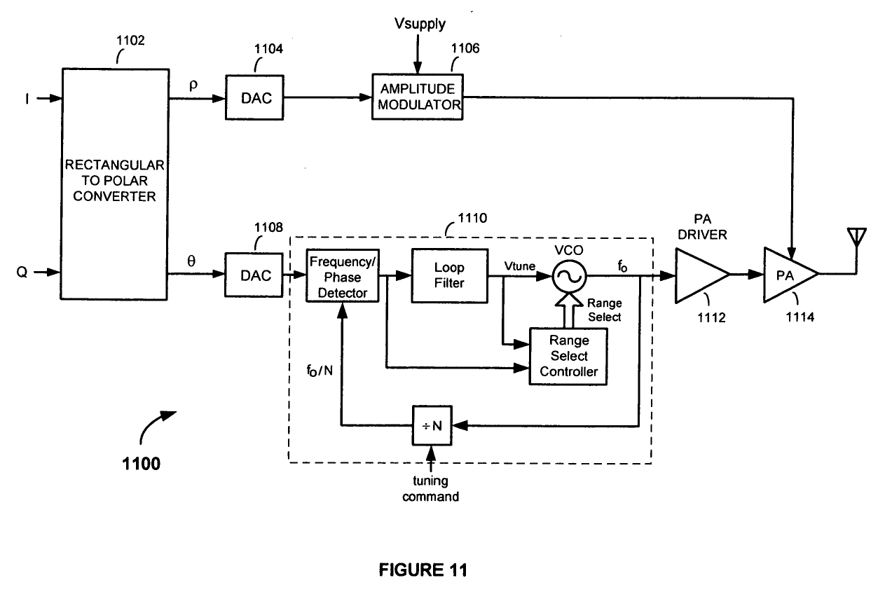

FIG. 11 shows another example in which the PLL circuit with the step-ranged VCO in FIG. 6 may be employed in a polar transmitter 1100, according to an embodiment of the present invention. The polar transmitter 1100 includes a rectangular-to-polar converter 1102 that is configured to receive I and Q data streams from a baseband modulator (not shown), and generate both an envelope signal containing amplitude information of the input signal and a constant-amplitude angle signal containing phase information of the input signal. The envelope signal is processed in an amplitude path of the transmitter 1100, while the angle signal is processed separately in a phase path of the transmitter 1100.

The amplitude path of the transmitter 1100 includes an amplitude-path digital-to-analog converter (DAC) 1104 and an amplitude modulator 1106. The phase path of the polar transmitter 1100 includes a phase-path DAC 1108, a PLL circuit 1110 having a fast range selection VCO, and a PA driver 1112. The output of the amplitude modulator 1106 in the amplitude path of the transmitter 1100 is coupled to a power input of an RF PA 1114, and the output of the PLL circuit 1110 is coupled to an RF input of a RF PA 1114 via a PA driver 1112.

During operation, the phase-path DAC 1108 is configured to receive the angle signal from the rectangular-to-polar converter 1102, and convert the angle signal into an analog signal. In response to a tuning command, the range select controller of the PLL circuit 1110 operates according to the frequency acquisition methods described above to provide a constant-amplitude phase modulated RF drive signal, which is coupled to the RF input of the PA 1114 via the PA driver 1112. Meanwhile, in the amplitude path, the amplitude-path DAC 1104 converts digital magnitude information into an analog amplitude signal. This analog signal is fed to the amplitude modulator 1106, which modulates a power supply voltage (Vsupply), according to the amplitude of the amplitude signal, thereby generating a modulated power supply voltage signal. The modulated power supply voltage signal from the amplitude path of the transmitter is coupled to the power input of the PA 1114.

Although the present invention has been described with reference to specific embodiments thereof, these embodiments are merely illustrative, and not restrictive, of the present invention. For example, while the range selection methods and apparatus in the exemplary embodiments have been described as employing voltage controlled oscillators (VCOs), the methods and apparatus of the present invention can be adapted to employ oscillator types that are controlled by other control mechanisms. For example, rather than using a tuning voltage from the control loop (i.e., Vtune) in the PLL circuit 600 in FIG. 6 to control the oscillator, a current could be sensed from the control loop and used to control a current controlled oscillator, as will be readily appreciated by those of ordinary skill in the art. Various other modifications or changes to the specifically disclosed exemplary embodiments will be suggested to persons skilled in the art and are to be included within the spirit and purview of the appended claims.

What is claimed is:

1. A frequency range selection apparatus, comprising:
a ranged controlled oscillator configured within a frequency control loop, said ranged controlled oscillator having a range setting input port and a fine tuning port; and
a range select controller configured outside the frequency control loop having a first input configured to receive an error signal from the frequency control loop, said error signal used by said range select controller to determine which one of a plurality of range select codes is to be applied to the range setting input port of the ranged controlled oscillator.

2. The frequency range selection apparatus of claim 1 wherein said range select controller has a second input port configured to receive a fine tuning signal from the frequency control loop.

3. The frequency range selection apparatus of claim 2 wherein the range select controller is operable to monitor the value of the fine tuning signal to determine whether a range select code applied to the range setting input port of the ranged controlled oscillator should be changed.

4. The frequency range selection apparatus of claim 2 wherein the frequency control loop comprises a phase-locked loop (PLL).

5. The frequency range selection apparatus of claim 4 wherein said error signal is provided by a phase detector configured within a main control loop of the PLL.

6. The frequency range selection apparatus of claim 4 wherein the fine tuning signal is provided by a loop filter configured within a main control loop of the PLL.

7. A frequency range selection apparatus, comprising:
a frequency locking loop circuit having a ranged controlled oscillator; and
a range select controller operable to provide range select codes to said ranged controlled oscillator,
wherein which one of a plurality of possible range select codes the range select controller is operable to provide to the ranged controlled oscillator is performed without having to open the frequency locking loop.

8. The frequency range selection apparatus of claim 7 wherein the frequency locking loop includes a feed-forward path and a feedback path, and range selection performed by said range select controller is accomplished using information obtained exclusively from the feed-forward path of the frequency locking loop.

9. The frequency range selection apparatus of claim 8 wherein said information includes an error signal received from a phase detector configured within said feed-forward path.

10. The frequency range selection apparatus of claim 8 wherein said information includes a fine tuning signal received from a loop filter configured within said feed-forward path.

11. The frequency range selection apparatus of claim 8 wherein said information further includes a fine tuning signal received from a loop filter configured within said feed-forward path.

12. The frequency range selection apparatus of claim 9 wherein a change in sign in the error signal is used by said range select controller to indicate that a proper range selection has been achieved.

13. The frequency range selection apparatus of claim 10 wherein, for a given range select code provided to the ranged controlled oscillator, the range select controller monitors the value of the fine tuning signal to determine whether the frequency lock loop is capable of stabilizing at the given range select setting.

14. The frequency range selection apparatus of claim 13 wherein the range select controller is operable to provide a different range select code to the ranged controlled oscillator if the fine tuning signal is determined to be greater than an upper tuning threshold or is determined to be less than a lower tuning threshold.

15. In a frequency locking loop containing a ranged controlled oscillator, a method of selecting a frequency range, comprising:
in response to a tuning command indicating a desired output frequency, applying a first range select code to a range setting input of a ranged controlled oscillator configured within a frequency locking loop;
determining whether the frequency locking loop is stabilizing to the desired output frequency at the first range setting; and
if the frequency locking loop is not stabilizing, and without opening the frequency locking loop, applying a second range select code to the range setting input of the ranged controlled oscillator.

16. The method of claim 15, further comprising determining a value of the second range select code that is more likely to result in the frequency loop stabilizing than when applying the first range select code.

17. The method of claim 15 wherein determining whether the frequency lock loop is stabilizing comprises measuring a value of a tuning signal provided at the output of a loop filter configured within the frequency lock loop.

18. The method of claim 15, further comprising detecting whether a sign of an error signal at the output of a phase detector configured within the frequency lock loop has changed following applying the second range select code to the range setting input of the ranged controlled oscillator.

19. The method of claim 15, further comprising estimating a range corresponding to the first range select code that is likely the most suitable range for the frequency specified by the tuning command.

20. The method of claim 15 wherein the first range select code applied to the range setting input of the ranged controlled oscillator is not determined based on a prior open-loop frequency measurement.

21. A radio communications transmitter, comprising:
an intermediate frequency (IF) stage configured to provide intermediate frequency IF information signals;
a radio frequency (RF) amplifier stage configured to provide radio frequency signals; and
a frequency translator disposed between the IF and RF amplifier stages operable to translate said IF information signals to RF signals, said frequency translator having:
a ranged controlled oscillator configured within a frequency control loop of said frequency translator; and
a range select controller configured outside said frequency control loop having a first input configured to receive an error signal from the frequency control loop, said error signal used by said range select controller to determine which one of a plurality of available range select codes to apply to a range setting input of the ranged controlled oscillator.

22. The radio communications transmitter of claim 21 wherein said range select controller has a second input port configured to receive a fine tuning signal from the frequency control loop.

23. The radio communications transmitter of claim 22 wherein the range select controller is operable to monitor the value of the fine tuning signal to determine whether a range select code applied to the range setting input port of the ranged controlled oscillator should be changed.

24. The radio communications transmitter of claim 22 wherein the frequency control loop comprises a phase-locked loop (PLL).

25. The radio communications transmitter of claim 21 wherein said error signal is provided by a phase detector configured within a main control loop of the PLL.

26. The radio communications transmitter of claim 24 wherein said error signal is provided by a phase detector configured within a main control loop of the PLL.

27. A polar transmitter, comprising:
an amplitude path configured to receive an envelope component of a communication signal;
a phase path having a frequency translator operable to translate a phase component of said communication signal to radio frequency (RF); and
a power amplifier having a power setting input configured to receive an amplitude modulated power supply from the amplitude path and an RF input configured to receive an RF phase component signal from said frequency translator,
wherein said frequency translator comprises:
a ranged controlled oscillator configured within a frequency control loop of said frequency translator; and
a range select controller configured outside said frequency control loop having a first input configured to receive an error signal from the frequency control loop, said error signal used by said range select controller to determine which one of a plurality of available range select codes to apply to a range setting input of the ranged controlled oscillator.

28. The polar transmitter of claim 27 wherein said range select controller has a second input port configured to receive a fine tuning signal from the frequency control loop.

29. The polar transmitter of claim 28 wherein the range select controller is operable to monitor the value of the fine tuning signal to determine whether a range select code applied to the range setting input port of the ranged controlled oscillator should be changed.

30. The polar transmitter of claim 28 wherein the frequency control loop comprises a phase-locked loop (PLL).

31. The polar transmitter of claim 27 wherein said error signal is provided by a phase detector configured within a main control loop of the PLL.

32. The polar transmitter of claim 30 wherein said error signal is provided by a phase detector configured within a main control loop of the PLL.
